(19) United States
(12) Patent Application Publication
(10) Pub. No.: US 2012/0201488 A1
(43) Pub. Date: Aug. 9, 2012

(54) Phase Shifting Device and a Method for Manufacturing the Same

(75) Inventors: Tsung-Yang Jason Liow, Singapore (SG); Guo Qiang Patrick Lo, Singapore (SG); Mingbin Yu, Singapore (SG); Qing Fang, Singapore (SG)

(73) Assignee: AGENCY FOR SCIENCE, TECHNOLOGY AND RESEARCH, Singapore (SG)

(21) Appl. No.: 13/379,734

(22) PCT Filed: Jun. 22, 2009
(86) PCT No.: PCT/SG09/00228

§ 371 Date: Mar. 12, 2012

(51) Int. Cl. G02F 1/035; H01L 21/02; G02B 6/12

(52) U.S. Cl. 385/3; 385/14; 438/31; 257/E21.002

(57) ABSTRACT

In an embodiment, a phase shifting device may be provided. The phase shifting device may include a supporting layer and a semiconducting layer disposed above the supporting layer. The semiconducting layer may include a first doped region doped with doping atoms of a first conductivity type and arranged on the supporting layer; and a second doped region doped with doping atoms of a second conductivity type being different from the first conductivity type; wherein the second doped region may be disposed over the first doped region such that a first doped regions junction may be formed in a direction substantially parallel to a surface of the supporting layer and a second doped regions junction may be formed in a direction substantially perpendicular to the surface of the supporting layer. A method of forming a phase shifting device and an electro-optic device may also be provided.

### TECHNICAL FIELD

Embodiments relate to a phase shifting device and a method of manufacturing the same.

### BACKGROUND

Long-haul fiber communications have provided high speed connectivity over long distances. The high performance optoelectronic components, which are essential for such applications, are capable of speeds up to 40 Gbps and beyond. By employing wavelength division multiplexing, terascale data rates can be attained. Currently, the majority of these high performance optoelectronic components utilize high cost materials such as III-V semiconductors and lithium niobate, which have intrinsic material properties that may be suitable for photonics. The prohibitive costs of fabrication and heterogeneous integration may limit the feasibility of adoption for short reach applications.

Silicon Photonics offers a cost advantage, due to low material costs and high volume manufacturability. Further, there is a potential for monolithic integration of photonic components with silicon Complementary metal-oxide-semiconductor (CMOS) on a single chip. Silicon photonic modulators are vital components for the realization of silicon photonic transceivers. Currently, silicon photonic modulators based on free carrier dispersion mechanism have been demonstrated with data transmission speeds of up to 40 Gb/s. The fastest of these modulators make use of carrier density modulation in a pn junction located in the waveguide phase-shifter. The pn junction is reverse-biased to operate in carrier depletion mode. A modulator with such a waveguide phase-shifter may possess good high speed scalability due to the low capacitance and ease of integration with traveling wave metal electrodes. However, a likely effect associated with such modulator structures may be such that the phase-shifters tend to be longer due to the weak overlap between the optical mode and the region of modulated carrier density.

Therefore, there is a need for an alternative phase-shifter or phase shifting device which may provide an increased overlap between the optical mode and the region of modulated carrier density with a comparable length.

### SUMMARY

In various embodiments, a phase shifting device may be provided. The phase shifting device may include a supporting layer and a semiconducting layer disposed above the supporting layer. The semiconducting layer may include a first doped region doped with doping atoms of a first conductivity type and arranged on the supporting layer; and a second doped region doped with doping atoms of a second conductivity type being different from the first conductivity type; wherein the second doped region may be disposed over the first doped region such that a first doped regions junction may be formed in a direction substantially parallel to a surface of the supporting layer and a second doped regions junction may be formed in a direction substantially perpendicular to the surface of the supporting layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of various embodiments. In the following description, various embodiments of the invention are described with reference to the following drawings, in which:

FIG. 1A shows a schematic view of an electro-optic device including a phase shifting device according to an embodiment; FIG. 1B shows a cross-sectional view of the phase shifting device taken along line A-A of FIG. 1A according to an embodiment;

FIGS. 2A to 2E show cross-sectional views illustrating a method for forming a phase shifting device according to an embodiment;

FIG. 3 show a flow diagram illustrating a method for forming a phase shifting device according to an embodiment;

FIG. 4 shows a simulated net dopant profile of a rib waveguide phase shifting device after dopant activation according to an embodiment;

FIG. 5A shows a plot of power (a.u.) vs wavelength (nm) at 0V and −2.5V bias of an asymmetric Mach-Zehnder Interferometric (MZI) modulator with a 4-mm-long phase shifting device according to an embodiment; FIG. 5B shows a plot of phase shift (°) vs voltage (V) at −2.5V bias of an asymmetric MZI modulator with a 4-mm-long phase shifting device according to an embodiment;

FIG. 6 shows an eyeline diagram captured using 2⁷−1 bits long pseudorandom binary sequence (PRBS) at a symbol rate of 2.5 Gb/s according to an embodiment;

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

The word “exemplary” is used herein to mean “serving as an example, instance, or illustration”. Any embodiment or design described herein as “exemplary” is not necessarily to be construed as preferred or advantageous over other embodiments or designs.

In various embodiment, an electro-optic device or a silicon optical modulator including a phase shifting device may be provided, which may enhance phase-shifting efficiency. The modulator may provide for a reduction in size and a relaxation of driver requirements.

In various embodiment, an electro-optic device including a phase shifting device may be provided, which may allow an enhancement of the modulation speed by optimizing the doping design to reduce parasitic series resistance.

An embodiment provides a phase shifting device. The device may include a supporting layer and a semiconducting layer disposed above the supporting layer. The semiconducting layer may include a first doped region doped with doping atoms of a first conductivity type and arranged on the supporting layer; and a second doped region doped with doping atoms of a second conductivity type being different from the first conductivity type; wherein the second doped region may be disposed over the first doped region such that a first doped regions junction may be formed in a direction substantially parallel to a surface of the supporting layer and a second doped regions junction may be formed in a direction substantially perpendicular to the surface of the supporting layer. The first doped region may be a p-type region and the second doped region may be an n-type region.

In an embodiment, the first doped region and the second doped region may form an optical waveguide.

In an embodiment, the optical waveguide may include a rib portion and a slab portion.

In an embodiment, within the rib portion of the optical waveguide, the n-type region may be disposed over the p-type region such that the n-type region may be L-shaped and the p-type region may be rectangle-shaped or square-shaped.

In an embodiment, the first doped region may include a rib portion doped with doping atoms of the first conductivity type and a slab portion doped with doping atoms of the first conductivity type.

In an embodiment, the second doped region may include a rib portion doped with doping atoms of the second conductivity type and a slab portion doped with doping atoms of the second conductivity type.

In an embodiment, the rib portion doped with doping atoms of the first conductivity type and the rib portion doped with doping atoms of the second conductivity type may form the rib portion of the optical waveguide.

In an embodiment, the slab portion doped with doping atoms of the first conductivity type and the slab portion doped with doping atoms of the second conductivity type may form the slab portion of the optical waveguide.

In an embodiment, the semiconducting layer may further include a first ohmic contact region of the first conductivity type positioned adjacent and in electrical contact with the first doped region. The first ohmic contact region may be termed the p+ contact.

In an embodiment, the semiconducting layer may further include a second ohmic contact region of the second conductivity type positioned adjacent and in electrical contact with the second doped region. The second ohmic contact region may be termed the n+ contact.

In an embodiment, the supporting layer may be an insulating layer or a dielectric layer.

In an embodiment, the supporting layer may include a silicon oxide (SiO₂), a buried oxide, silicon nitride (Si₃N₄) or silicon carbide (SiC).

In an embodiment, the semiconducting layer may include silicon (Si), polysilicon (poly-Si), gallium arsenide (GaAs), germanium (Ge), silicon-germanium (SiGe). The semiconducting layer may include any other suitable semiconductor materials.

In an embodiment, the phase shifting device may further include a further semiconducting layer, wherein the supporting layer may be disposed over the further semiconducting layer.

In an embodiment, the further semiconducting layer may further include Si, poly-Si, GaAs, Ge, SiGe. The further semiconducting layer may include any other suitable semiconductor materials. The further semiconducting layer may be the same or different from the semiconducting layer.

In an embodiment, the semiconducting layer, the supporting layer and the further semiconducting layer may include a silicon-on-insulator (SOI) layer structure.

In an embodiment, the semiconducting layer may include a thickness in the range of about 100 nm to 300 nm, e.g. about 220 nm. The further semiconducting layer may include a thickness in the range of about 100 nm to 300 nm, e.g. about 220 nm. The further semiconducting layer may be of the same or different thickness from the semiconducting layer. The supporting layer may include a thickness in the range of about 1 μm to 10 μm, e.g. about 2 μm.

In an embodiment, the first ohmic contact region of the first conductivity type may include a doping concentration higher than the doping concentration of the first doped region. The first ohmic contact region may include a doping concentration of about 5×10¹⁹ cm⁻³ to 5×10²⁰ cm⁻³.

In an embodiment, the second ohmic region of the second conductivity type may include a doping concentration higher than the doping concentration of the second doped region. The second ohmic contact region may include a doping concentration of about 5×10¹⁹ cm⁻³ to 5×10²⁰ cm⁻³. The doping concentration of the second ohmic contact region may be the same or different from the doping concentration of the first ohmic contact region.

In an embodiment, the first doped region may include a doping concentration of about 5×10¹⁶ cm⁻³ to 5×10¹⁸ cm⁻³. The first doped region may include a consistent doping concentration throughout the first doped region or may include a varied doping concentration within the first doped region. The first doped region may include a doping concentration profile with one or more peaks depending on user and design requirements.

In an embodiment, the second doped region may include a doping concentration of about 5×10¹⁶ cm⁻³ to 5×10¹⁸ cm⁻³. The second doped region may include a doping concentration which may be the same or different from the first doped region depending on user and design requirements. The second doped region may include a consistent doping concentration throughout the second doped region or may include a varied doping concentration within the second doped region. The second doped region may include a doping concentration profile with one or more peaks depending on user and design requirements.

In an embodiment, the first conductivity type may be a p-type. P-type dopants may include boron, aluminium, gallium.

In an embodiment, the second conductivity type may be an n-type. N-type dopants may include phosphorus, arsenic, antimony.

In an embodiment, the first doped regions junction may include a pn junction.

In an embodiment, the second doped regions junction may include a pn junction. The first doped regions junction may be the same or different from the second doped regions junction.

An embodiment provides a method of forming a phase shifting device. The method may include forming a semiconducting layer above the supporting layer; forming a first doped region on the supporting layer by doping the semiconducting layer with doping atoms of a first conductivity type; forming a second doped region by doping the semiconducting layer with doping atoms of a second conductivity type being different from the first conductivity type; and forming the second doped region over the first doped region such that a first doped regions junction may be formed in a direction substantially parallel to a surface of the supporting layer and a second doped regions junction may be formed in a direction substantially perpendicular to the surface of the supporting layer.

In an embodiment, forming the first doped region and the second doped region may include forming an optical waveguide.

In an embodiment, forming the optical waveguide may include forming a rib portion and a slab portion.

In an embodiment, forming the first doped region may include forming a rib portion doped with doping atoms of the first conductivity type and a slab portion doped with doping atoms of the first conductivity type.

In an embodiment, forming the second doped region may include forming a rib portion doped with doping atoms of the second conductivity type and a slab portion doped with doping atoms of the second conductivity type.

In an embodiment, forming the rib portion doped with doping atoms of the first conductivity type and the rib portion doped with doping atoms of the second conductivity type may include forming the rib portion of the optical waveguide.

In an embodiment, forming the slab portion doped with doping atoms of the first conductivity type and the slab portion doped with doping atoms of the second conductivity type may include forming the slab portion of the optical waveguide.

In an embodiment, the method may further include forming a first ohmic contact region of the first conductivity type adjacent and in electrical contact with the first doped region by doping the semiconducting layer with doping atoms of the first conductivity type.

In an embodiment, the method may further include forming a second ohmic contact region of the second conductivity type adjacent and in electrical contact with the second doped region by doping the semiconducting layer with doping atoms of the second conductivity type.

In an embodiment, the supporting layer may be an insulating layer.

In an embodiment, the supporting layer may include SiO₂, a buried oxide, silicon nitride (Si₃N₄), silicon carbide (SiC).

In an embodiment, the semiconducting layer may include Si, poly-Si, GaAs, Ge, SiGe.

In an embodiment, the method may further include forming the supporting layer over a further semiconducting layer.

In an embodiment, the further semiconducting layer may include Si, poly-Si, GaAs, Ge, SiGe.

In an embodiment, forming the semiconducting layer, the supporting layer and the further semiconducting layer may include forming a silicon-on-insulator layer structure.

In an embodiment, forming the first ohmic contact region of the first conductivity type may include forming the first ohmic contact region with a doping concentration higher than the doping concentration of the first doped region.

In an embodiment, forming the second ohmic region of the second conductivity type may include forming the second ohmic contact region with a doping concentration higher than the doping concentration of the second doped region.

In an embodiment, the first doped region may include a doping concentration of about 5×10¹⁶ cm⁻³ to 5×10¹⁸ cm⁻³.

In an embodiment, the second doped region may include a doping concentration of about 5×10¹⁶ cm⁻³ to 5×10¹⁸ cm⁻³.

In an embodiment, the first conductivity type may be a p-type.

In an embodiment, the second conductivity type may be an n-type.

In an embodiment, the first doped regions junction may include a pn junction.

In an embodiment, the second doped regions junction may include a pn junction.

An embodiment provides an electro-optic device. The electro-optic device may include an optical source for providing an optical signal; a splitter for splitting the optical signal into a first optical signal and a second optical signal; a phase shifting device for receiving the first optical signal and providing a first phase modulated optical signal; a further phase shifting device for receiving the second optical signal and providing a second phase modulated optical signal; and a combiner for combining the first phase modulated optical signal and the second phase modulated optical signal to produce a resultant optical signal; wherein the further phase shifting device may include a length longer than the phase shifting device. The electro-optic device may be termed the modulator. The further phase shifting device may also include a length substantially equal or similar to the phrase shifting device.

In an embodiment, the further phase shifting device may include a configuration or structure the same as the phase shifting device.

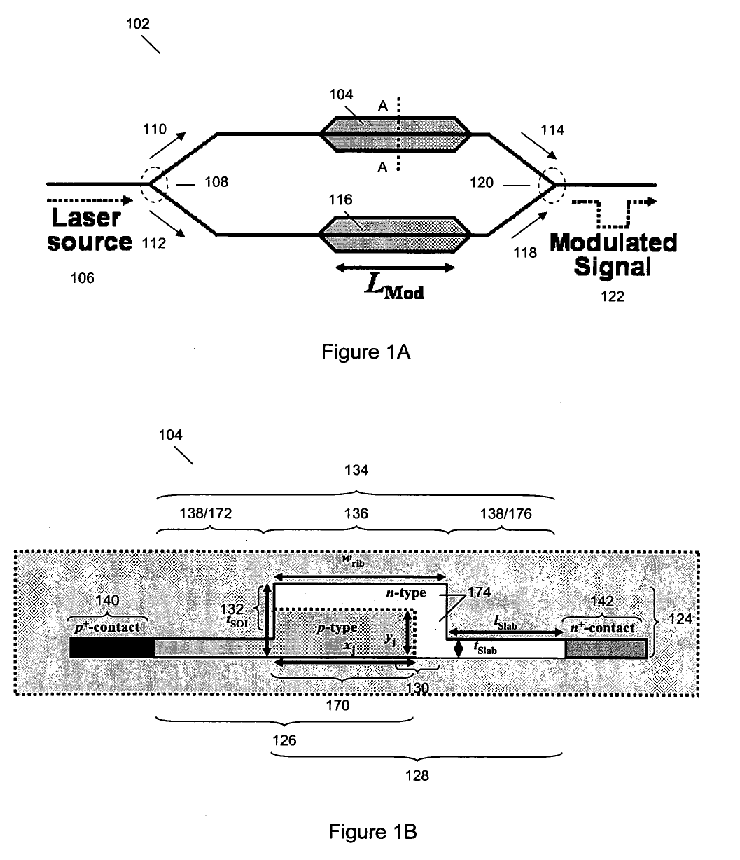

FIG. 1A shows a schematic view of an electro-optic device 102 including a phase shifting device 104 according to an embodiment. The electro-optic device 102 or modulator may include an optical source or a laser source (not shown) for providing an input optical signal 106, a splitter 108 for splitting the input optical signal 106 into a first optical signal 110 and a second optical signal 112. The electro-optic device 102 may include a phase shifting device 104 for receiving the first optical signal 110 and providing a first phase modulated optical signal 114 and a further phase shifting device 116 for receiving the second optical signal 112 and providing a second phase modulated optical signal 118. The electro-optic device 102 may further include a combiner 120 for combining the first phase modulated optical signal 114 and the second phase modulated optical signal 118 to produce a resultant optical signal 122, wherein the further phase shifting device 116 may include a length longer than the phase shifting device 104. The further phase shifting device 116 may include a configuration or structure the same as the phase shifting device 104. The length of the further phase shifting device 116 may be represented by L_{MOD}.

FIG. 1B shows a cross-sectional view of the phase shifting device 104 taken along line A-A of FIG. 1A according to an embodiment. The phase shifting device 104 may include a supporting layer (not shown) and a semiconducting layer 124 disposed above the supporting layer. The semiconducting layer 124 may include a first doped region 126 doped with doping atoms of a first conductivity type or a p-type region and arranged on the supporting layer; and a second doped region 128 doped with doping atoms of a second conductivity type, or an n-type region, the second conductivity being different from the first conductivity type; wherein the second doped region 128 may be disposed over the first doped region 126 such that a first doped regions junction 130 may be formed in a direction substantially parallel to a surface of the supporting layer and a second doped regions junction 132 may be formed in a direction substantially perpendicular to the surface of the supporting layer.

The first conductivity type may be a p-type and the second conductivity type may be an n-type.

The first doped region 126 and the second doped region 128 may form an optical waveguide 134. The optical waveguide 134 may include a rib portion 136 and a slab portion 138.

The first doped region 126 may include a rib portion doped with doping atoms of the first conductivity type 170 and a slab portion doped with doping atoms of the first conductivity type 172. The second doped region 128 may include a rib portion doped with doping atoms of the second conductivity type 174 and a slab portion doped with doping atoms of the second conductivity type 176.

The rib portion doped with doping atoms of the first conductivity type or p-type dopants 170 and the rib portion doped with doping atoms of the second conductivity type or n-type dopants 174 may form the rib portion 136 of the optical waveguide 134. The slab portion doped with doping atoms of the first conductivity type 172 and the slab portion doped with doping atoms of the second conductivity type 176 may form the slab portion 138 of the optical waveguide 134.

The semiconducting layer 124 may further include a first ohmic contact region 140 of the first conductivity type or p+ contact positioned adjacent and in electrical contact with the first doped region 126. The semiconducting layer 124 may further include a second ohmic contact region 142 of the second conductivity type or n+ contact positioned adjacent and in electrical contact with the second doped region 128.

The supporting layer may be an insulating layer. The supporting layer may include a SiO₂, a buried oxide, Si₃N₄, SiC. The semiconducting layer 124 may include Si, poly-Si, GaAs, Ge, SiGe.

The phase shifting device 104 may include a further semiconducting layer (not shown), wherein the supporting layer may be disposed over the further semiconducting layer. The further semiconducting layer may include Si, poly-Si, GaAs, Ge, SiGe.

The semiconducting layer 124, the supporting layer and the further semiconducting layer may include a silicon-on-insulator (SOI) layer structure or SOI substrate.

The first ohmic contact region 140 of the first conductivity type may include a doping concentration higher than the doping concentration of the first doped region 126. The second ohmic contact region 142 of the second conductivity type may include a doping concentration higher than the doping concentration of the second doped region 128.

The first doped region 126 may include a doping concentration of about --. The second doped region 128 may include a doping concentration of about --. The first ohmic contact region 140 may include a doping concentration of about --. The second ohmic contact region 142 may include a doping concentration of about --.

The first doped regions junction 130 may include a pn junction. The second doped regions junction 132 may include a pn junction. The first doped regions junction 130 may be the same as the second doped regions junction 132.

The semiconducting layer 124 may include a thickness in the range of about 100 nm to 300 nm, e.g. about 220 nm. The further semiconducting layer may include a thickness in the range of about 100 nm to 300 nm, e.g. about 220 nm. The further semiconducting layer may be of the same or different thickness from the semiconducting layer 124. The supporting layer may include a thickness in the range of about 1 μm to 10 μm, e.g. about 2 μm.

The height of the rib portion 136 may be determined by the thickness of the semiconducting layer 124. The height of the rib portion 136 may be represented by t_{SOI}. The width of the rib portion 136 may be represented by w_{rib}.

The height or thickness of the slab portion 138 may be determined by the thickness of the semiconducting layer 124 etch depth. The height or thickness of the slab portion 138 may be represented by t_{slab} and may be in the range of about 10 nm to 100 nm, e.g. 60 nm. The dimensions of the slab portion 138 may be configured such that the optical mode may be highly confined within the rib portion 136 of the optical waveguide 134.

The breadth of the rib portion doped with p-type dopants 170 may be represented by xj and the height of the rib portion doped with p-type dopants 170 may be represented by yj. The location of the rib portion 136 within the optical waveguide 134 may be determined by ion implantation and anneal conditions. For example, both the breadth (xj) and height (yj) may be controlled by accurate ion implantation processes and may be independent of lithographic misalignment. Therefore, a reasonable device-to-device uniformity may be obtained. The breadth (xj) of the rib portion doped with p-type dopants 170 may be in the range of about 10% to 90% of w_{rib} (for example w_{rib} may be about 500 nm, xj may be about 280 nm). The height (yj) of the rib portion doped with p-type dopants 170 may be in the range of about 10% to 90% of t_{SOI} (for example t_{SOI} may be about 220 nm, xj may be about 130 nm).

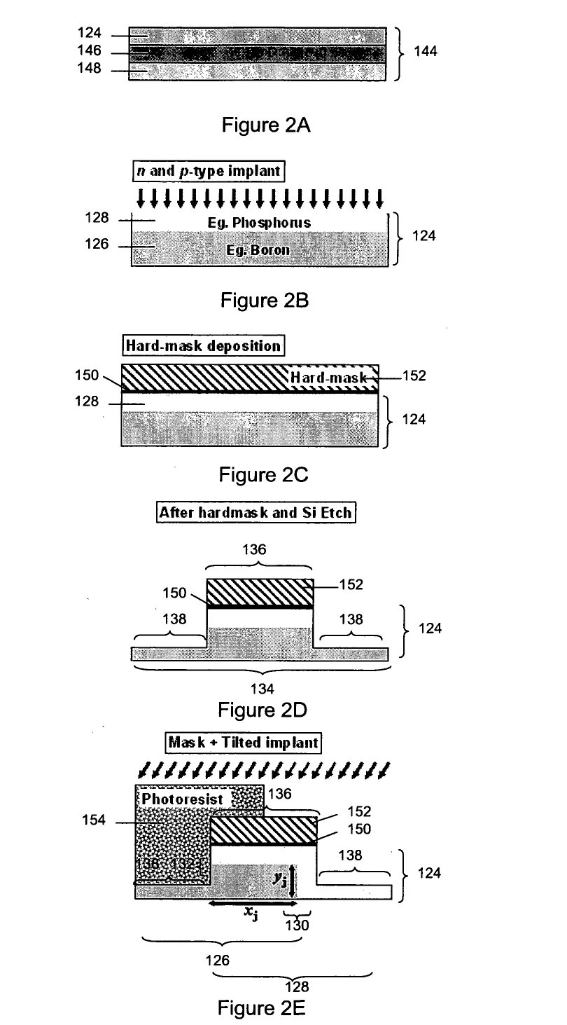

FIGS. 2A to 2E show cross-sectional views illustrating a method for forming a phase shifting device 104 according to an embodiment.

In FIG. 2A, a silicon-on-insulator (SOI) substrate 144 may be provided. The SOI substrate 144 may include a semiconducting layer 124 disposed above a supporting layer 146, and the supporting layer 146 further disposed above a further semiconducting layer 148.

The semiconducting layer 124 may include silicon (Si), polysilicon (poly-Si), gallium arsenide (GaAs), germanium (Ge), silicon-germanium (SiGe) or any other semiconductor materials. The further semiconducting layer 148 may include Si, poly-Si, GaAs, Ge, SiGe or any other semiconductor materials. The further semiconducting layer 148 may be of the same or different material from the semiconducting layer 124. The supporting layer 146 may include an insulating layer. The supporting layer 146 may include a silicon oxide layer, a buried oxide layer, silicon nitride (Si₃N₄), silicon carbide (SiC) or any other suitable oxide layers.

The semiconducting layer 124 may include a thickness in the range of about 100 nm to 300 nm, e.g. about 220 nm. The further semiconducting layer 148 may include a thickness in the range of about 100 nm to 300 nm, e.g. about 220 nm. The further semiconducting layer 148 may be of the same or different thickness from the semiconducting layer 124. The supporting layer 146 may include a thickness in the range of about 1 μm to 10 μm, e.g. about 2 μm.

In FIG. 2B, a first doped region or p-type region 126 may be formed on the supporting layer (not shown) by doping the semiconducting layer 124 with doping atoms of a first conductivity type or p-type dopants. A second doped region or n-type dopants 128 may be formed by doping the semiconducting layer 124 with doping atoms of a second conductivity type, or n-type dopants, the second conductivity type being different from the first conductivity type. The first conductivity type may include p-type and the second conductivity type may include n-type. P-type dopants or doping atoms may include boron, aluminium and n-type dopants or doping atoms may include phosphorus, arsenic. The first doped region 126 and the second doped region 128 may be formed by ion implantation of p-type and n-type dopants to two depths within the semiconducting layer 124. The p-type dopants may be implanted into a deeper depth into the semiconducting layer 124 and the n-type dopants may be implanted into a shallower depth into the semiconducting layer 124.

In FIG. 2C, hard mask deposition may be carried out. First a dielectric layer 150 may be deposited over the semiconducting layer 124, preferably in contact with the second doped region 128 or the n-type region. The dielectric layer 150 may also include silicon oxide (SiO₂) or any other suitable material which may serve to protect the n-type region 128 before the subsequent deposition of a hard mask layer 152. The dielectric layer 150 may include a thickness in the range of about 1 nm to 50 nm, e.g. about 10 nm.

Next a hard mask layer 152 may be deposited over the dielectric layer 150, the hard mask layer 152 may protect the dielectric layer 150 in subsequent etching steps. The hard mask layer 152 may include silicon nitride (SiN, Si₃N₄) or any other suitable materials suitable to act as an etch barrier. The hard mask layer 152 may include a thickness in the range of about 10 nm to 200 nm, e.g. about 100 nm.

In FIG. 2D, a photoresist layer (not shown) may be deposited on the hard mask layer 152. The photoresist layer may then be patterned to form an optical waveguide 134 pattern including a rib portion 136 and a slab portion 138 by standard photolithography techniques. Subsequently, using the patterned photoresist layer as a mask, portions of the hard mask layer 152 not covered by the photoresist mask may be etched away by an anisotropic etching process such as Reactive Ion Etching (RIE). Then, respective portions of the dielectric layer 150 and the semiconducting layer 124 may also be etched to form an optical waveguide 134 including a rib portion 136 and a slab portion 138. This may be followed by photoresist strip (PRS) and wet clean.

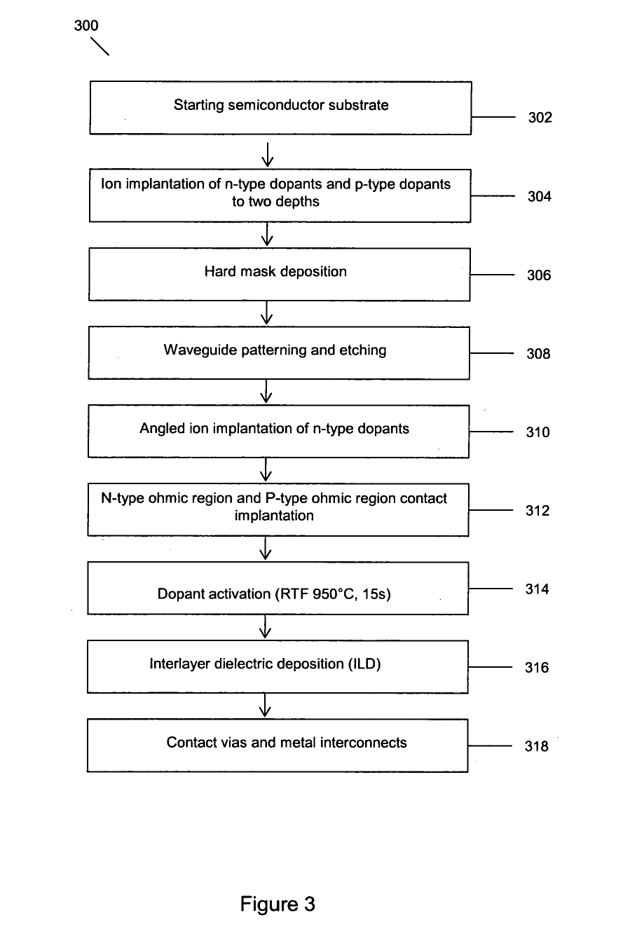

In FIG. 2E, an angled implantation of n-type dopants may be carried out. A further photoresist layer 154 may be deposited over a portion of the structure formed in FIG. 2D, for example the structure including the hard mask layer 152, the dielectric layer 150 and the semiconducting layer 124. As a portion of the hard mask layer 152 may not be removed, a top surface of the rib portion 136 may be protected from implantation while one side or a sidewall of the rib portion 136 and the slab portion 138 between the rib portion 136 and the subsequent second ohmic contact region or n+ contact (not shown) to be formed may be implanted. Implantation in a tilted direction may be carried out such that the n-type region 128 may be formed over the p-type region 126 such that a first pn junction or first doped regions junction 130 may be formed in a direction substantially parallel to a surface of the supporting layer (not shown) and a second pn junction or second doped regions junction 132 may be formed in a direction substantially perpendicular to the surface of the supporting layer. The rest of the process steps for forming a phase shifting device 104 may be disclosed in the flow diagram as shown in FIG. 3.

FIG. 3 show a flow diagram illustrating a method for forming a phase shifting device 104 according to an embodiment.

The method 300 begins at 302 with a starting semiconductor substrate 144, for example a SOI substrate 144, including a semiconducting layer 124 disposed above a supporting layer 146 and the supporting layer 146 further disposed above a further semiconducting layer 148. Next, in 304, ion implantation of n-type dopants and p-type dopants to two depths may be carried out. Further, in 306, hard mask deposition may be carried out. In this regard, a dielectric layer 150 may be deposited on the semiconducting layer 124. A hard mask layer 152 may be deposited over the dielectric layer 150. Then, in 308, a optical waveguide 134 patterning and etching may be carried out. This may involve deposition of a photoresist layer on the hard mask layer 152. The photoresist layer may be patterned using photolithography techniques to form an optical waveguide 134 pattern. Using the patterned photoresist as a mask, portions of the hard mask layer 152 not covered by the photoresist mask may be etched away. Then, the dielectric layer 150, and the semiconducting layer 124 may be etched to form an optical waveguide 134 including a rib portion 136 and a slab portion 138. This may be followed by PRS and wet clean. Then, in 310, a further photoresist layer 154 may be deposited over a structure including the hard mask layer 152, the dielectric layer 150 and the semiconducting layer 124. An angled implantation of n-type dopants may be carried out such that the n-type region 128 may be formed over the p-type region 126 such that a first pn junction 130 may be formed in a direction substantially parallel to a surface of the supporting layer 146 and a second pn junction 132 may be formed in a direction substantially perpendicular to the surface of the supporting layer 146. In 312, n-type ohmic region and p-type ohmic region contact implantation may be carried out to form the n+ contact 142 and the p+ contact 140. In 314, the n-type and p-type dopants may be activated. The dopant activation may be carried out using Rapid Thermal Furnace (RTF) at about 950° C. and for about 15 s. Then in 316, an interlayer dielectric deposition (ILD) may be carried out. The interlayer dielectric may include a thickness in the range of about 0.2 μm to 4 μm and serve to electrically isolate metal interconnects or electrodes subsequently formed. It may also serve as the waveguide cladding. Finally, in 318, contact vias may be formed and this may be followed by deposition of metal to form the metal interconnects.

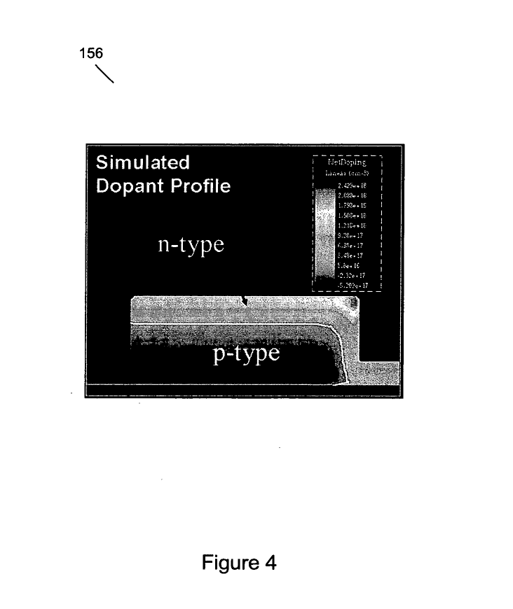

FIG. 4 shows a simulated net dopant profile 156 of a rib waveguide phase shifting device 104 after dopant activation according to an embodiment.

The net dopant profile within the rib waveguide phase-shifting device 104 or phase-shifter after dopant activation may first be simulated using a Technology Computer Aided Design (TCAD) process simulator. The position of the metallurgical junction (or pn junction) and the dopant profile may be easily controlled by tuning the ion implantation and annealing conditions. For optimum compatibility with CMOS fabrication, a typical Rapid Thermal Anneal (RTA) spike anneal condition may be utilized. The desired dopant profile may still be easily achieved by tuning the ion implantation conditions alone. Simulations for two different anneal conditions of about 950° C. for about 15 s and about 1030° C. for about 5 s may be performed. The simulated dopant profiles for both conditions may be similar.

In FIG. 4, dopant activation may be performed at about 950° C. for about 15 s. The simulated dopant profile 156 may disclose the formation of two pn junctions 130, 132 with both vertically and horizontally-oriented portions within the rib portion 136 of the optical waveguide 134.

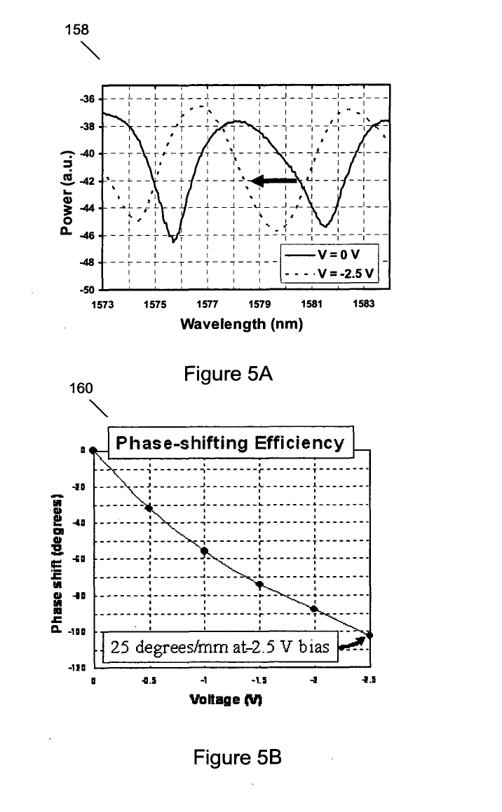

FIG. 5A shows a plot 158 of power (a.u.) vs wavelength (nm) at 0V and −2.5V bias of an asymmetric Mach-Zehnder Interferometric (MZI) modulator 102 with a 4-mm-long phase shifting device 104 according to an embodiment and FIG. 5B shows a plot 160 of phase shift (degrees) vs voltage (V) at 2.5V bias of an asymmetric MZI modulator 102 with a 4-mm-long phase shifting device 104 according to an embodiment.

The output spectra of a modulator 102 with phase shifting device 104 or phase-shifters of about 4 mm in length may be measured to obtain the relationship between phase-shift and phase-shifter bias. The measurement setup may use an Amplified Spontaneous Emission (ASE) light source. Light may be coupled into and out of the optical waveguide 134 using single-mode lensed fibers. The output may then be connected to an optical spectrum analyzer. The measured spectra for bias voltages of about 0 and −2.5 V may be shown in FIG. 5A. By applying a phase-shifter bias of about −2.5 V to one of the two phase-shifter arms, the junction depletion width may increase, which may essentially reduce the hole density and may cause a corresponding change in the effective refractive index. The phase change (Δφ) may be calculated using equation 1, where Δλ is the wavelength shift and FSR is the Free Spectral Range of the Mach-Zehnder interferometer.

$$Δϕ = \frac{2 πΔλ}{F S R} \qquad ( 1 )$$

The phase-shift at different bias voltages may be extracted using equation 1 and may be plotted in FIG. 5B. At a bias of −2.5 V, the calculated Δφ may be about 100°. This may correspond to a normalized phase-shift of about 25°/mm. This may be different from the state of the art depletion mode modulators which solely employ either lateral or vertical p-n junctions and typically achieve about 11°/mm at the same bias voltage. The improved performance may be attributed to the increased overlap between the optical mode and the region of carrier density modulation as a result of the phase-shifter 104 structure. The thin SOI rib portion 136, which may be only about 220 nm in height, may confine the optical mode vertically. This may ensure that the peak of the optical mode may be located near the vertical pn junction portion 132. In addition, the horizontal pn junction portion 130 may also overlap with the optical mode. Hence, a change in the phase-shifter bias may simultaneously change the hole concentration near the respective vertical 132 and horizontal 130 pn junctions, and may significantly improve the modulation efficiency.

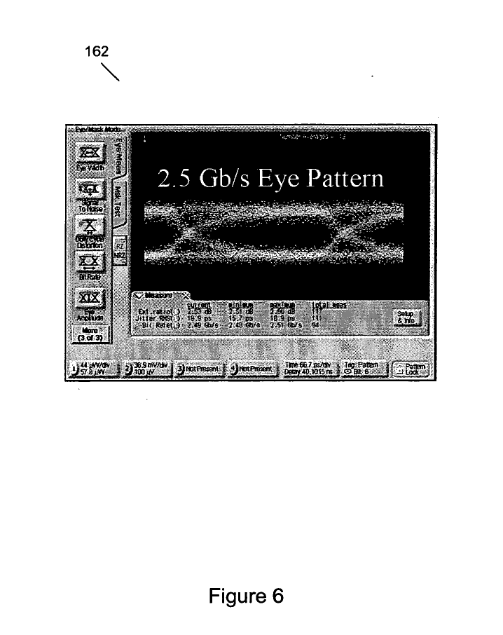

FIG. 6 shows an eyeline diagram 162 captured using 2⁷−1 bits long pseudorandom binary sequence (PRBS) at a symbol rate of 2.5 Gb/s according to an embodiment.

The high speed performance of the modulator 102 may be evaluated from the eyeline diagram 162 measurement. For this measurement, the modulator 102 may be driven in single-ended mode (only one phase-shifter arm driven). The drive signal may be obtained by combining a DC bias voltage (V_{bias}=−1.5 V) with the AC RF drive signal (V_{RF,p-p}=2.7 V) from the modulator driver using a bias tee. The drive signal used may be lower than the state of the art.

FIG. 6 shows the measured eyeline diagram 162 at 2.5 Gb/s. From series resistance extraction and capacitance measurements, it may be deduced that the bandwidth may be limited by the high series resistance in the low-doped regions between the highly-doped contacts and the pn junction (BW∝(2πRC)⁻¹) and the total capacitance (Cₜₒₜₐₗ).

Higher speed performance may be achieved by optimizing the doping design to reduce the parasitic series resistance. There may be two ways to reduce the series resistance. One way may be to reduce the contact resistance by Ni silicidation at the region of contact between the metal electrode and the ohmic contact regions and the other way may be to reduce the optical waveguide 134 slab resistance by increasing the doping concentration and reducing the slab length l_{slab}.

Higher speed performance may also be achieved by reducing the total capacitance. The total capacitance may be reduced by reducing the length of the phase shifting device, taking advantage of the higher efficiency.

Using a cut-back method, the normalized loss in the phase-shifter 104 may be extracted to be about 1 dB/mm. This may be comparable or better than that of other similar depletion-mode modulators.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A phase shifting device, comprising:
a supporting layer;
a semiconducting layer disposed above the supporting layer, the semiconducting layer comprising:
a first doped region doped with doping atoms of a first conductivity type and arranged on the supporting layer; and
a second doped region doped with doping atoms of a second conductivity type being different from the first conductivity type
wherein the second doped region is disposed over and in direct contact with the first doped region such that a first doped regions junction is formed in a direction substantially parallel to a surface of the supporting layer and a second doped regions junction is formed in a direction substantially perpendicular to the surface of the supporting layer

2. The phase shifting device of claim 1,
wherein the first doped region and the second doped region form an optical waveguide.

3. The phase shifting device of claim 2,
wherein the optical waveguide comprises a rib portion and a slab portion, the rib portion and the slab portion are configured such that an optical mode is substantially confined within the rib portion of the optical waveguide.

4. The phase shifting device of claim 1,
wherein the first doped region comprises a rib portion doped with doping atoms of the first conductivity type and a slab portion doped with doping atoms of the first conductivity type, and
wherein the second doped region comprises a rib portion doped with doping atoms of the second conductivity type and a slab portion doped with doping atoms of the second conductivity type.

5. (canceled)

6. The phase shifting device of claim 4,
wherein the rib portion doped with doping atoms of the first conductivity type and the rib portion doped with doping atoms of the second conductivity type form the rib portion of the optical waveguide.

7. The phase shifting device of claim 4,
wherein the slab portion doped with doping atoms of the first conductivity type and the slab portion doped with doping atoms of the second conductivity type form the slab portion of the optical waveguide.

8. The phase shifting device of claim 1,
wherein the semiconducting layer further comprises a first ohmic contact region of the first conductivity type positioned adjacent and in electrical contact with the first doped region.

9. The phase shifting device of claim 1,
wherein the semiconducting layer further comprises a second ohmic contact region of the second conductivity type positioned adjacent and in electrical contact with the second doped region.

10-12. (canceled)

13. The phase shifting device of claim 1,
further comprising a further semiconducting layer, wherein the supporting layer is disposed over the further semiconducting layer.

14-15. (canceled)

16. The phase shifting device of claim 8,
wherein the first ohmic contact region of the first conductivity type comprises a doping concentration higher than the doping concentration of the first doped region.

17. The phase shifting device of claim 9,
wherein the second ohmic region of the second conductivity type comprises a doping concentration higher than the doping concentration of the second doped region.

18-23. (canceled)

24. A method of forming a phase shifting device, the method comprising:
forming a semiconducting layer above a supporting layer;
forming a first doped region on the supporting layer by doping the semiconducting layer with doping atoms of a first conductivity type;
forming a second doped region by doping the semiconducting layer with doping atoms of a second conductivity type being different from the first conductivity type; and
forming the second doped region over and in direct contact with the first doped region such that a first doped regions junction is formed in a direction substantially parallel to a surface of the supporting layer and a second doped regions junction is formed in a direction substantially perpendicular to the surface of the supporting layer.

25. The method of claim 24,
wherein forming the first doped region and the second doped region comprises forming an optical waveguide.

26. The method of claim 25,
wherein forming the optical waveguide comprises forming a rib portion and a slab portion, the rib portion and the slab portion are configured such that an optical mode is substantially confined within the rib portion of the optical waveguide.

27. The method of claim 24,
wherein forming the first doped region comprises forming a rib portion doped with doping atoms of the first conductivity type and a slab portion doped with doping atoms of the first conductivity type; and
wherein forming the second doped region comprises forming a rib portion doped with doping atoms of the second conductivity type and a slab portion doped with doping atoms of the second conductivity type.

28. (canceled)

29. The method of claim 27,
wherein forming the rib portion doped with doping atoms of the first conductivity type and the rib portion doped with doping atoms of the second conductivity type comprises forming the rib portion of the optical waveguide.

30. The method of claim 27,
wherein forming the slab portion doped with doping atoms of the first conductivity type and the slab portion doped with doping atoms of the second conductivity type comprises forming the slab portion of the optical waveguide.

31. The method of claim 24,
further comprising forming a first ohmic contact region of the first conductivity type adjacent and in electrical contact with the first doped region by doping the semiconducting layer with doping atoms of the first conductivity type.

32. The method of claim 24,
further comprising forming a second ohmic contact region of the second conductivity type adjacent and in electrical contact with the second doped region by doping the semiconducting layer with doping atoms of the second conductivity type.

33-46. (canceled)

47. An electro-optic device comprising:
an optical source for providing an optical signal;
a splitter for splitting the optical signal into a first optical signal and a second optical signal;
a phase shifting device of any one of claims 1 to 23 for receiving the first optical signal and providing a first phase modulated optical signal;
a further phase shifting device for receiving the second optical signal and providing a second phase modulated optical signal; and
a combiner for combining the first phase modulated optical signal and the second phase modulated optical signal to produce a resultant optical signal;
wherein the further phase shifting device comprises a length longer than the phase shifting device.

48. (canceled)
